(19) United States
(12) Patent Application Publication
(10) Pub. No.: US 2026/0100686 A1
(43) Pub. Date: Apr. 9, 2026

(54) FILTER CIRCUIT

(71) Applicant: Murata Manufacturing Co., Ltd., Nagaokakyo-shi (JP)

(72) Inventor: Naofumi TAKEZONO, Nagaokakyo-shi (JP)

(21) Appl. No.: 19/342,773

(22) Filed: Sep. 29, 2025

(30) Foreign Application Priority Data
Oct. 9, 2024 (JP) 2024-177238

(51) Int. Cl. H03H 7/01; H03H 1/00

(52) U.S. Cl. CPC H03H 7/0115; H03H 1/00; H03H 2001/0085

(57) ABSTRACT

A filter circuit includes an inductor formed by serially connecting wiring line groups formed on a plurality of conductive layers of the board through a via and a capacitor in which a first wiring line having one end of the inductor of the wiring line groups overlaps, as viewed in a direction orthogonal to a main surface of the board, a third wiring line that is formed on one of the conductive layers that is adjacent, in the direction orthogonal to the main surface of the board, to another of the conductive layers on which the first wiring line is formed and has one end electrically connected, through a via, to a second wiring line having another end of the inductor of the wiring line groups.

### CROSS REFERENCE TO RELATED APPLICATION

This application claims priority from Japanese Patent Application No. 2024-177238, filed on Oct. 9, 2024. The content of this application is incorporated herein by reference in its entirety.

### BACKGROUND OF THE DISCLOSURE

### 1. Field of the Disclosure

The present disclosure relates to a filter circuit.

### 2. Description of the Related Art

Japanese Unexamined Patent Application Publication No. 2008-211764 describes an LC parallel resonant circuit formed by using conductive layers of a board.

### BRIEF SUMMARY OF THE DISCLOSURE

In the LC parallel resonant circuit described in Japanese Unexamined Patent Application Publication No. 2008-211764, the case in which one conductive layer that forms one electrode of a capacitor and another conductive layer that forms the other electrode (referred to below as a layer shift in the present disclosure) relatively shift from each other in the surface direction of the board will be considered.

When a layer shift occurs between one conductive layer that forms one electrode of the capacitor and another conductive layer that forms the other electrode of the capacitor, the overlapping area between the two electrodes as viewed in the vertical direction of the board changes. When the overlapping area between one electrode and the other electrode of the capacitor changes, the electrostatic capacity of the capacitor changes from the design value, and the characteristics of the LC parallel resonant circuit change from the design value. That is, when a layer shift occurs in the LC parallel resonant circuit described in Japanese Unexamined Patent Application Publication No. 2008-211764, the characteristics change from the design value.

The present disclosure addresses the problems described above with a possible benefit of suppressing the characteristics from changing even when a layer shift occurs.

According to an aspect of the present disclosure, there is provided a filter circuit formed on a board, including: an inductor formed by serially connecting wiring line groups formed on a plurality of conductive layers of the board through a via; and a capacitor in which a first wiring line having one end of the inductor of the wiring line groups overlaps, as viewed in a direction orthogonal to a main surface of the board, a third wiring line, formed on one of the conductive layers that is adjacent, in the direction orthogonal to the main surface of the board, to another of the conductive layers on which the first wiring line is formed, the third wiring line having one end electrically connected, through a via, to a second wiring line having another end of the inductor of the wiring line groups.

According to an aspect of the present disclosure, there is provided a filter circuit formed on a board, including: an inductor formed by serially connecting wiring line groups formed on a plurality of conductive layers of the board through a via; and a capacitor in which a tip of a first projecting portion that projects inward of a first wiring line having one end of the inductor of the wiring line groups overlaps, as viewed in a direction orthogonal to a main surface of the board, a tip of a second projecting portion that projects inward of a second wiring line having another end of the inductor of the wiring line groups, the first projecting portion being a portion of the first wiring line and having a winding shape, the second projecting portion being a portion of the second wiring line.

According to the present disclosure, even when a layer shift occurs, the characteristics can be suppressed from changing.

### BRIEF DESCRIPTION OF THE SEVERAL VIEWS OF THE DRAWINGS

FIG. 1 is an equivalent circuit diagram of a filter circuit according to a first embodiment;

FIG. 2 is a diagram for describing the multilayer structure of a board in which the filter circuit according to the first embodiment is formed;

FIG. 3 is a perspective view of the filter circuit according to the first embodiment;

FIG. 4 is a diagram illustrating the shapes of wiring lines on conductive layers of the filter circuit according to the first embodiment;

FIG. 5 is a diagram illustrating a first wiring line and a second wiring line of the filter circuit according to the first embodiment that overlap each other;

FIG. 6 is a diagram illustrating the results of circuit simulation of the filter circuit according to the first embodiment;

FIG. 7 is a diagram for describing the multilayer structure of a board in which a filter circuit according to a second embodiment is formed;

FIG. 8 is a perspective view of the filter circuit according to the second embodiment;

FIG. 9 is a diagram illustrating the shapes of wiring lines on conductive layers of the filter circuit according to the second embodiment; and

FIG. 10 is a diagram illustrating a first wiring line and a third wiring line of the filter circuit according to the second embodiment that overlap each other.

### DETAILED DESCRIPTION OF THE DISCLOSURE

Embodiments of the present disclosure will be described in detail below with reference to the drawings. It should be noted that the present disclosure is not limited to the embodiments. The embodiments are illustrative, and it will be appreciated that partial substitutions or combinations of the structures illustrated in different embodiments are possible. In the second and subsequent embodiments, matters common to the first embodiment will not be described, and only the differences will be described. In particular, the similar operations and effects resulting from the same structure will not be described sequentially for each of the embodiments.

### First Embodiment

### Structure

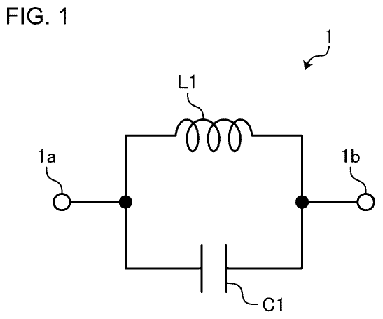

FIG. 1 is an equivalent circuit diagram of a filter circuit according to a first embodiment.

A filter circuit 1 includes an inductor L1 and a capacitor C1 that are connected in parallel to each other between a first terminal 1a and a second terminal 1b. That is, the filter circuit 1 is an LC parallel circuit. The filter circuit 1 is formed in a board which is, for example, a printed wiring board (PWB).

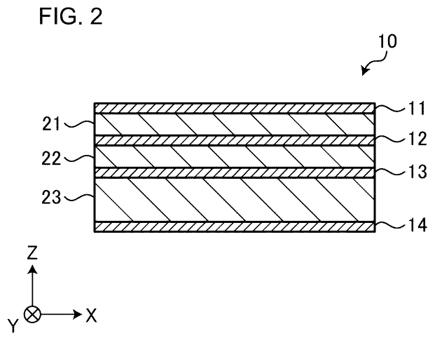

FIG. 2 is a diagram for describing the multilayer structure of a board in which the filter circuit according to the first embodiment is formed.

The board 10 includes first to fourth conductive layers 11 to 14 and first to third dielectric layers 21 to 23.

The first dielectric layer 21 is formed between the first conductive layer 11 and the second conductive layer 12. The second dielectric layer 22 is formed between the second conductive layer 12 and the third conductive layer 13. The third dielectric layer 23 is formed between the third conductive layer 13 and the fourth conductive layer 14.

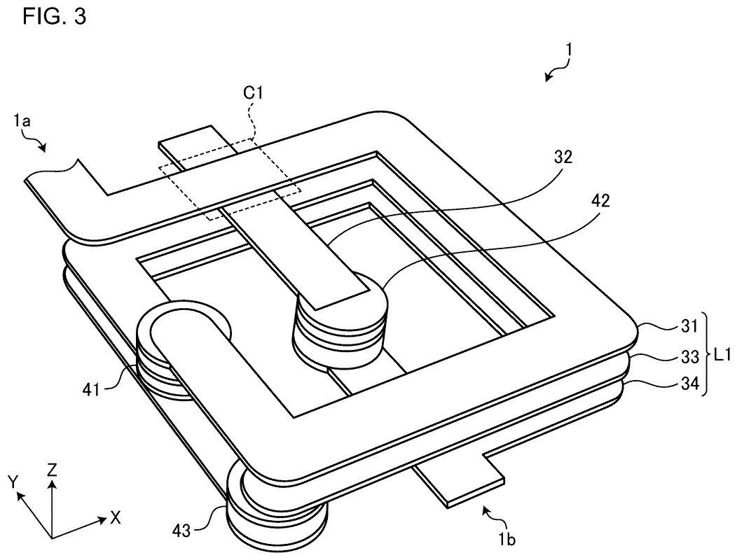

FIG. 3 is a perspective view of the filter circuit according to the first embodiment. In FIG. 3, only the conductive layers are illustrated, and the dielectric layers are not illustrated.

The filter circuit 1 includes first to fourth wiring lines 31 to 34. The first wiring line 31 is formed on the first conductive layer 11 (see FIG. 2). The second wiring line 32 is formed on the second conductive layer 12 (see FIG. 2). The third wiring line 33 is formed on the third conductive layer 13 (see FIG. 2). The fourth wiring line 34 is formed on the fourth conductive layer 14 (see FIG. 2).

The first wiring line 31, the third wiring line 33, and the fourth wiring line 34 correspond to an example of the wiring line groups according to the present disclosure. The first wiring line 31 corresponds to an example of the first wiring line according to the present disclosure. The fourth wiring line 34 corresponds to an example of the second wiring line according to the present disclosure. The second wiring line 32 corresponds to an example of the third wiring line according to the present disclosure.

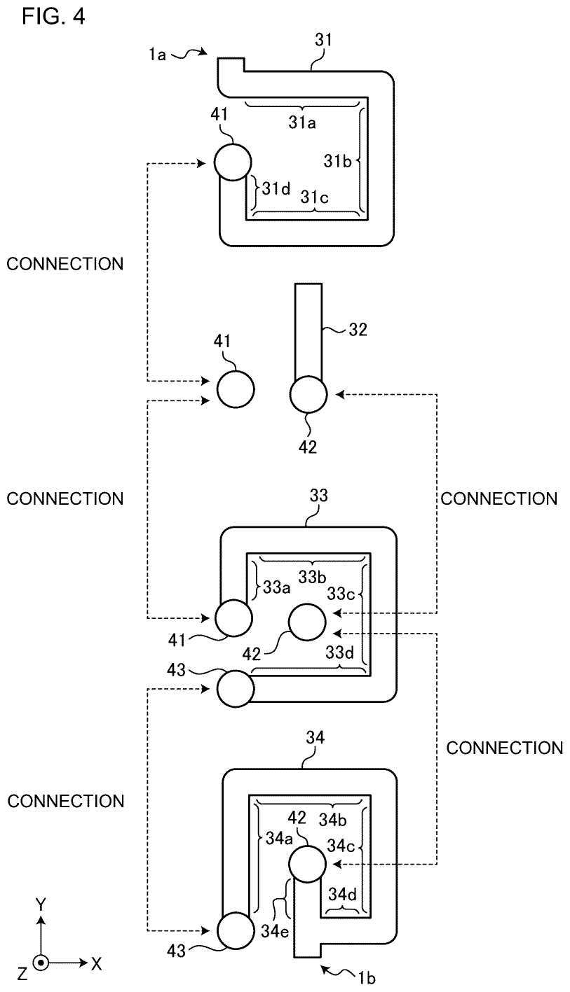

FIG. 4 is a diagram illustrating the shapes of the wiring lines on the conductive layers of the filter circuit according to the first embodiment.

Referring to FIGS. 3 and 4, one end of the first wiring line 31 is the first terminal 1a (see FIG. 1). The first wiring line 31 is wound clockwise in plan.

In plan view, the board 10 is viewed in a direction orthogonal to the main surface (XY plane) of the board 10 (the board 10 is viewed in a direction opposite to the Z-axis direction).

The first wiring line 31 includes a first portion 31a, a second portion 31b, a third portion 31c, and a fourth portion 31d.

The first portion 31a has one end that is the first terminal 1a and extends in the X-axis direction. The second portion 31b has one end connected to the other end of the first portion 31a and extends in a direction opposite to the Y-axis direction. The third portion 31c has one end connected to the other end of the second portion 31b and extends in a direction opposite to the X-axis direction.

The fourth portion 31d has one end connected to the other end of the third portion 31c and extends in the Y-axis direction.

The other end of the fourth portion 31d is connected to the third wiring line 33 through a via 41.

One end of the second wiring line 32 is connected to the fourth wiring line 34 through a via 42. The via 42 is formed at a location corresponding to substantially the center of the first wiring line 31 having a winding shape in plan view. The second wiring line 32 extends in the Y-axis direction.

One end of the third wiring line 33 is connected to the via 41. The third wiring line 33 is wound clockwise in plan view.

The third wiring line 33 includes a first portion 33a, a second portion 33b, a third portion 33c, and a fourth portion 33d.

The first portion 33a has one end connected to the via 41 and extends in the Y-axis direction. The second portion 33b has one end connected to the other end of the first portion 33a and extends in the X-axis direction. The third portion 33c has one end connected to the other end of the second portion 33b and extends in the direction opposite to the Y-axis direction. The fourth portion 33d has one end connected to the other end of the third portion 33c and extends in the direction opposite to the X-axis direction.

The other end of the fourth portion 33d is connected to the fourth wiring line 34 through a via 43.

One end of the fourth wiring line 34 is connected to the via 43. The fourth wiring line 34 is wound clockwise in plan view.

The fourth wiring line 34 includes a first portion 34a, a second portion 34b, a third portion 34c, and a fourth portion 34d.

The first portion 34a has one end connected to the via 43 and extends in the Y-axis direction. The second portion 34b has one end connected to the other end of the first portion 34a and extends in the X-axis direction. The third portion 34c has one end connected to the other end of the second portion 34b and extends in the direction opposite to the Y-axis direction. The fourth portion 34d has one end connected to the other end of the third portion 34c and extends in the direction opposite to the X-axis direction.

The other end of the fourth portion 34d is the second terminal 1b (see FIG. 1).

The fourth wiring line 34 further includes a fifth portion 34e that extends in the Y-axis direction from the second terminal 1b. One end of the fifth portion 34e is connected to the second terminal 1b. The other end of the fifth portion 34e is connected to one end of the second wiring line 32 through the via 42.

The first wiring line 31, the third wiring line 33, and the fourth wiring line 34 are connected in series through the via 41 and the via 43 to form the inductor L1.

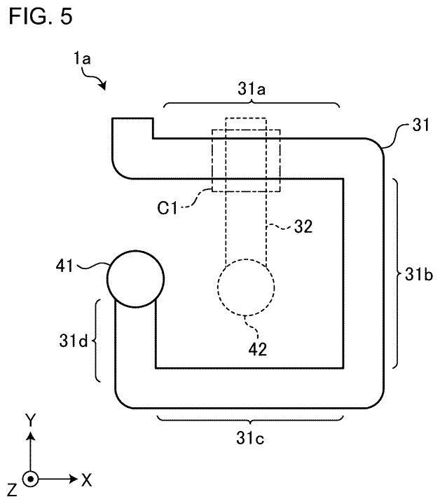

FIG. 5 is a diagram illustrating the first wiring line and the second wiring line of the filter circuit according to the first embodiment that overlap each other.

The first portion 31a of the first wiring line 31 overlaps the second wiring line 32 so as to form a plus (+) shape in plan view.

One end of the first portion 31a of the first wiring line 31 is the first terminal 1a of the filter circuit 1. In addition, the second wiring line 32 is connected to the second terminal 1b of the filter circuit 1 through the via 42 and the fifth portion 34e of the fourth wiring line 34. Accordingly, the overlapping portion between the first portion 31a of the first wiring line 31 and the second wiring line 32 forms the capacitor C1 (see FIG. 1).

### Circuit Simulation

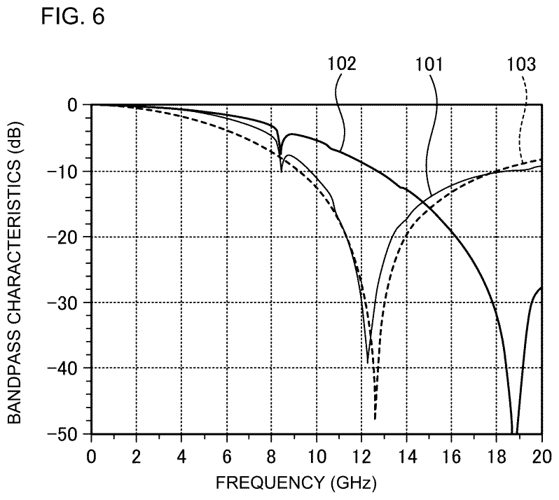

FIG. 6 is a diagram illustrating the results of circuit simulation of the filter circuit according to the first embodiment. In FIG. 6, the horizontal axis represents the frequency (GHz), and the vertical axis represents the bandpass characteristics (dB).

Line 101 indicates the results of circuit simulation of the filter circuit 1 according to the first embodiment.

Line 102 indicates the results of circuit simulation of a first comparative example. The first comparative example is the inductor L1 obtained by the capacitor C1 being removed from the filter circuit 1. That is, the first comparative example is the inductor L1 obtained by the second wiring line 32, the via 42, and the fifth portion 34e of the fourth wiring line 34 illustrated in FIGS. 3 and 4 being removed from the filter circuit 1.

Line 103 is a diagram illustrating the results of circuit simulation of a second comparative example. The second comparative example is a surface mount device (SMD) that achieves the filter circuit 1 illustrated in FIG. 1.

As illustrated in line 101 and line 103, the filter circuit 1 according to the first embodiment has bandpass characteristics close to those of the second comparative example (the surface mount device that achieves the filter circuit).

It should be noted that the first comparative example (inductor L1) has bandpass characteristics that are significantly different from those of the second comparative example, as indicated by line 102 and line 103.

### Effects

Referring to FIG. 5, the first portion 31a of the first wiring line 31 overlaps the second wiring line 32 so as to form a plus (+) shape in plan view. Accordingly, even when the first wiring line 31 and the second wiring line 32 relatively shift from each other in the X-axis direction (that is, when a relative layer shift in the X-axis direction occurs), the overlapping area between the first portion 31a of the first wiring line 31 and the second wiring line 32 in plan view is suppressed from changing. That is, the electrostatic capacity of the capacitor C1 is suppressed from changing.

Accordingly, in the filter circuit 1, even when the first wiring line 31 and the second wiring line 32 relatively shift from each other in the X-axis direction, the bandpass characteristics can be suppressed from changing.

In addition, the first portion 31a of the first wiring line 31 overlaps the second wiring line 32 so as to form a plus (+) shape in plan view. Accordingly, even when the first wiring line 31 and the second wiring line 32 relatively shift from each other in the Y-axis direction (when a relative layer shift in the Y-axis direction occurs), the overlapping area between the first portion 31a of the first wiring line 31 and the second wiring line 32 in plan view is suppressed from changing. That is, the electrostatic capacity of the capacitor C1 is suppressed from changing.

Accordingly, in the filter circuit 1, even when the first wiring line 31 and the second wiring line 32 relatively shift from each other in the Y-axis direction, the bandpass characteristics can be suppressed from changing.

In addition, even when the first wiring line 31 and the second wiring line 32 relatively shift from each other in the X-axis direction and relatively shift from each other in the Y-axis direction, the overlapping area between the first portion 31a of the first wiring line 31 and the second wiring line 32 in plan view is suppressed from changing. That is, the electrostatic capacity of the capacitor C1 is suppressed from changing.

Accordingly, in the filter circuit 1, even when the first wiring line 31 and the second wiring line 32 relatively shift from each other in the X-axis direction and relatively shift from each other in the Y-axis direction, the bandpass characteristics can be suppressed from changing.

### First Modification

The first portion 31a of the first wiring line overlaps the second wiring line 32 so as to form a plus (+) shape in the example in FIGS. 4 and 5, but the present disclosure is not limited to this example. The length of the second wiring line 32 in the Y-axis direction may be reduced such that the first portion 31a of the first wiring line overlaps the second wiring line 32 so as to form a T-shape.

As a result, even when the first wiring line 31 and the second wiring line 32 relatively shift from each other in the X-axis direction (when a relative layer shift in the X-axis direction occurs), the overlapping area between the first portion 31a of the first wiring line 31 and the second wiring line 32 is suppressed from changing. That is, the electrostatic capacity of the capacitor C1 is suppressed from changing.

Accordingly, in the filter circuit 1, even when the first wiring line 31 and the second wiring line 32 relatively shift from each other in the X-axis direction, the bandpass characteristics can be suppressed from changing.

### Second Modification

The angle formed by the first portion 31a of the first wiring line 31 and the second wiring line 32 in plan view is substantially 90° in the example illustrated in FIGS. 4 and 5, but the present disclosure is not limited to this example. The angle formed by the first portion 31a of the first wiring line 31 and the second wiring line 32 in plan view may be substantially 45° or other angles.

### Third Modification

The inductor L1 includes three conductive layers including the first wiring line 31, the third wiring line 33, and the fourth wiring line 34 in the example illustrated in FIGS. 4 and 5, but the present disclosure is not limited to this example. The inductor L1 may include two conductive layers or four or more conductive layers.

### Fourth Modification

The first wiring line 31, the third wiring line 33, and the fourth wiring line 34 each have a rectangular shape in plan view in the example illustrated in FIGS. 4 and 5, but the present disclosure is not limited to this example. The first wiring line 31, the third wiring line 33, and the fourth wiring line 34 may each have a circular shape or other shapes in plan view.

### Second Embodiment

### Structure

Since the equivalent circuit diagram of the filter circuit 1A according to the second embodiment is the same as the equivalent circuit diagram of the filter circuit 1 according to the first embodiment (see FIG. 1), illustration and description thereof are omitted.

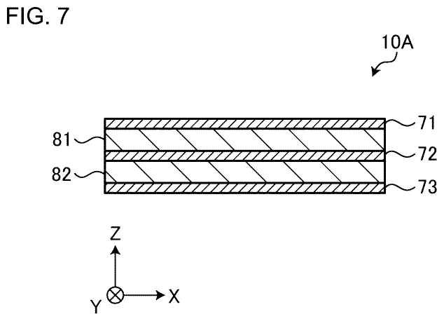

FIG. 7 is a diagram for describing the multilayer structure of a board in which the filter circuit according to the second embodiment is formed.

A board 10A includes first to third conductive layers 71 to 73 and first and second dielectric layers 81 and 82.

The first dielectric layer 81 is formed between the first conductive layer 71 and the second conductive layer 72. The second dielectric layer 82 is formed between the second conductive layer 72 and the third conductive layer 73.

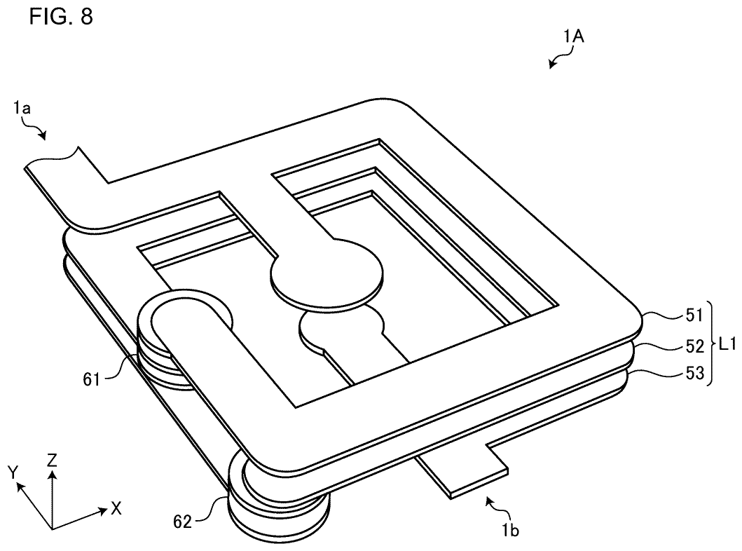

FIG. 8 is a perspective view of the filter circuit according to the second embodiment. In FIG. 8, only the conductive layers are illustrated, and the dielectric layers are not illustrated.

The filter circuit 1A includes first to third wiring lines 51 to 53. The first wiring line 51 is formed on the first conductive layer 71 (see FIG. 7). The second wiring line 52 is formed on the second conductive layer 72 (see FIG. 7). The third wiring line 53 is formed on the third conductive layer 73 (see FIG. 7).

The first to third wiring lines 51 to 53 correspond to an example of the wiring line groups according to the present disclosure. The first wiring line 51 corresponds to an example of the first wiring line according to the present disclosure. The third wiring line 53 corresponds to an example of the second wiring line according to the present disclosure.

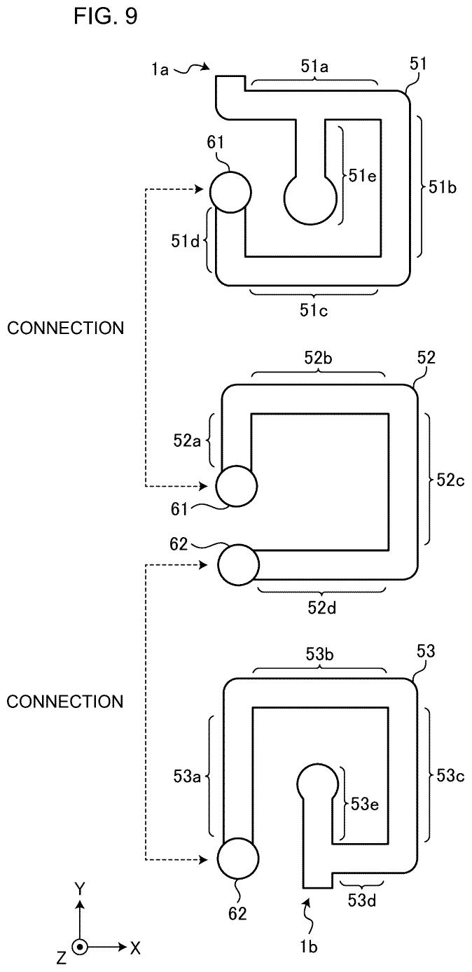

FIG. 9 is a diagram illustrating the shapes of the wiring lines on the conductive layers of the filter circuit according to the second embodiment.

Referring to FIGS. 8 and 9, one end of the first wiring line 51 is the first terminal 1a (see FIG. 1). The first wiring line 51 is wound clockwise in plan view.

The first wiring line 51 includes a first portion 51a, a second portion 51b, a third portion 51c, and a fourth portion 51d.

The first portion 51a has one end that is the first terminal 1a and extends in the X-axis direction. The second portion 51b has one end connected to the other end of the first portion 51a and extends in the direction opposite to the Y-axis direction. The third portion 51c has one end connected to the other end of the second portion 51b and extends in the direction opposite to the X-axis direction. The fourth portion 51d has one end connected to the other end of the third portion 51c and extends in the Y-axis direction.

The other end of the fourth portion 51d is connected to the second wiring line 52 through a via 61.

The first wiring line 51 further includes a fifth portion 51e that extends in the direction opposite to the Y-axis direction from the first portion 51a. One end of the fifth portion 51e is connected to the first portion 51a. The other end of the fifth portion 51e is located at a location corresponding to substantially the center of the first wiring line 51 in plan view. The other end of the fifth portion 51e has a circular shape in plan view.

The fifth portion 51e of the first wiring line 51 corresponds to an example of the first projecting portion according to the present disclosure.

One end of the second wiring line 52 is connected to the via 61. The second wiring line 52 is wound clockwise in plan view.

The second wiring line 52 includes a first portion 52a, a second portion 52b, a third portion 52c, and a fourth portion 52d.

The first portion 52a has one end connected to the via 61 and extends in the Y-axis direction. The second portion 52b has one end connected to the other end of the first portion 52a and extends in the X-axis direction. The third portion 52c has one end connected to the other end of the second portion 52b and extends in the direction opposite to the Y-axis direction. The fourth portion 52d has one end connected to the other end of the third portion 52c and extends in the direction opposite to the X-axis direction.

The other end of the fourth portion 52d is connected to the third wiring line 53 through the via 62.

One end of the third wiring line 53 is connected to the via 62. The third wiring line 53 is wound clockwise in plan view.

The third wiring line 53 includes a first portion 53a, a second portion 53b, a third portion 53c, and a fourth portion 53d.

The first portion 53a has one end connected to the via 62 and extends in the Y-axis direction. The second portion 53b has one end connected to the other end of the first portion 53a and extends in the X-axis direction. The third portion 53c has one end connected to the other end of the second portion 53b and extends in the direction opposite to the Y-axis direction. The fourth portion 53d has one end connected to the other end of the third portion 53c and extends in the direction opposite to the X-axis direction.

The other end of the fourth portion 53d is the second terminal 1b (see FIG. 1).

The third wiring line 53 further includes a fifth portion 53e that extends in the Y-axis direction from the second terminal 1b. One end of the fifth portion 53e is connected to the second terminal 1b. The other end of the fifth portion 53e is formed at a location corresponding to substantially the center of the third wiring line 53 in plan view. The other end of the fifth portion 53e has a circular shape in plan view.

The fifth portion 53e of the third wiring line 53 corresponds to an example of the second projecting portion according to the present disclosure.

The first wiring line 51, the second wiring line 52, and the third wiring line 53 are connected in series through the via 61 and the via 62 to form the inductor L1.

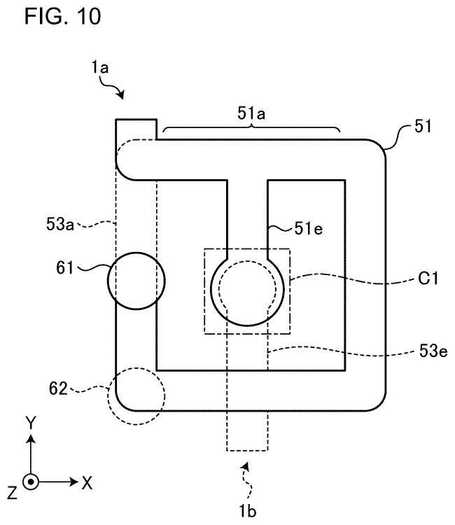

FIG. 10 is a diagram illustrating the first wiring line and the third wiring line of the filter circuit according to the second embodiment that overlap each other.

The other end (circular portion) of the fifth portion 51e of the first wiring line 51 and the other end (circular portion) of the fifth portion 53e of the third wiring line 53 overlap each other in plan view.

One end of the first portion 51a of the first wiring line 51 is the first terminal 1a of the filter circuit 1A. In addition, one end of the fifth portion 51e of the first wiring line 51 is connected to the first portion 51a. In addition, one end of the fifth portion 53e of the third wiring line 53 is connected to the second terminal 1b of the filter circuit 1A. Accordingly, the overlapping portion between the fifth portion 51e of the first wiring line 51 and the fifth portion 53e of the third wiring line 53 forms the capacitor C1 (see FIG. 1).

The other end (circular portion) of the fifth portion 51e of the first wiring line 51 is larger than the other end (circular portion) of the fifth portion 53e of the third wiring line 53 in plan view. That is, the other end of the fifth portion 51e of the first wiring line 51 includes the other end of the fifth portion 53e of the third wiring line 53 in plan view.

### Effects

Referring to FIG. 9, the other end (circular portion) of the fifth portion 51e of the first wiring line 51 and the other end (circular portion) of the fifth portion 53e of the third wiring line 53 overlap each other in plan view. In addition, the other end of the fifth portion 51e of the first wiring line 51 is larger than the other end of the fifth portion 53e of the third wiring line 53 in plan view.

Accordingly, even when the first wiring line 51 and the third wiring line 53 relatively shift from each other in the X-axis direction, the overlapping area between the other end of the fifth portion 51e of the first wiring line 51 and the other end of the fifth portion 53e of the third wiring line 53 in plan view is suppressed from changing. That is, the electrostatic capacity of the capacitor C1 is suppressed from changing.

As a result, in the filter circuit 1A, even when the first wiring line 51 and the third wiring line 53 relatively shift from each other in the X-axis direction, the bandpass characteristics can be suppressed from changing.

In addition, the other end of the fifth portion 51e of the first wiring line 51 and the other end of the fifth portion 53e of the third wiring line 53 overlap each other in plan view. In addition, the other end of the fifth portion 51e of the first wiring line 51 is larger than the other end of the fifth portion 53e of the third wiring line 53 in plan view.

Accordingly, even when the first wiring line 51 and the third wiring line 53 relatively shift from each other in the Y-axis direction, the overlapping area between the other end of the fifth portion 51e of the first wiring line 51 and the other end of the fifth portion 53e of the third wiring line 53 in plan view is suppressed from changing. That is, the electrostatic capacity of the capacitor C1 is suppressed from changing.

Accordingly, in the filter circuit 1A, even when the first wiring line 51 and the third wiring line 53 relatively shift from each other in the Y-axis direction, the bandpass characteristics can be suppressed from changing.

In addition, even when the first wiring line 51 and the third wiring line 53 relatively shift from each other in the X-axis direction and relatively shift from each other in the Y-axis direction, the overlapping area between the other end of the fifth portion 51e of the first wiring line 51 and the other end of the fifth portion 53e of the third wiring line 53 in plan view is suppressed from changing. That is, the electrostatic capacity of the capacitor C1 is suppressed from changing.

Accordingly, in the filter circuit 1A, even when the first wiring line 51 and the third wiring line 53 relatively shift from each other in the X-axis direction and relatively shift from each other in the Y-axis direction, the bandpass characteristics can be suppressed from changing.

### First Modification

The other end (circular portion) of the fifth portion 51e of the first wiring line is larger than the other end (circular portion) of the fifth portion 53e of the third wiring line 53 in plan view in the example illustrated in FIGS. 9 and 10, but the present disclosure is not limited to this example. The other end of the fifth portion 53e of the third wiring line 53 may be larger than the other end of the fifth portion 51e of the first wiring line 51 in plan view.

### Second Modification

The other end of the fifth portion 51e of the first wiring line and the other end of the fifth portion 53e of the third wiring line 53 each have a circular shape in plan view in the example illustrated in FIGS. 9 and 10, but the present disclosure is not limited to this example. The other end of the fifth portion 51e of the first wiring line and the other end of the fifth portion 53e of the third wiring line 53 may each have an elliptical shape, a rectangular shape, a polygonal shape, or the like in plan view.

### Third Modification

The angle formed by the fifth portion 51e of the first wiring line and the fifth portion 53e of the third wiring line 53 is substantially 180° in plan view in the example illustrated in FIGS. 9 and 10, but the present disclosure is not limited to this example. The angle formed by the fifth portion 51e of the first wiring line and the fifth portion 53e of the third wiring line 53 may be substantially 45°, substantially 90°, or other angles in plan view.

### Fourth Modification

The inductor L1 includes the three conductive layers including the first wiring line 51, the second wiring line 52, and the third wiring line 53 in the example illustrated in FIGS. 9 and 10, but the present disclosure is not limited to this example. The inductor L1 may include two conductive layers or four or more conductive layers.

### Fifth Modification

The first wiring line 51, the second wiring line 52, and the third wiring line 53 each have a rectangular shape in plan view in the example illustrated in FIGS. 9 and 10, but the present disclosure is not limited to this example. The first wiring line 51, the second wiring line 52, and the third wiring line 53 may each have a circular shape or other shapes in plan view.

### Examples of Structure of Present Disclosure

The present disclosure can have the following structure.
(1) A filter circuit formed on a board, comprising: an inductor formed by serially connecting wiring line groups formed on a plurality of conductive layers of the board through a via; and a capacitor in which a first wiring line having one end of the inductor of the wiring line groups overlaps, as viewed in a direction orthogonal to a main surface of the board, a third wiring line, formed on one of the conductive layers that is adjacent to another of the conductive layers on which the first wiring line is formed, the third wiring line having one end electrically connected, through a via, to a second wiring line having another end of the inductor of the wiring line groups.
(2) The filter circuit according to (1), wherein the first wiring line and the third wiring line overlap each other so as to form a+shape as viewed in the direction orthogonal to the main surface of the board.
(3) The filter circuit according to (1), wherein the first wiring line and the third wiring line overlap each other so as to form a T-shape as viewed in the direction orthogonal to the main surface of the board.
(4) A filter circuit formed on a board, comprising: an inductor formed by serially connecting wiring line groups formed on a plurality of conductive layers of the board through a via; and a capacitor in which a tip of a first projecting portion that projects inward of a first wiring line having one end of the inductor of the wiring line groups overlaps, as viewed in a direction orthogonal to a main surface of the board, a tip of a second projecting portion that projects inward of a second wiring line having another end of the inductor of the wiring line groups, the first projecting portion being a portion of the first wiring line, the second projecting portion being a portion of the second wiring line.
(5) The filter circuit according to (4), wherein a size of the tip of the first projecting portion is larger than a size of the tip of the second projecting portion as viewed in the direction orthogonal to the main surface of the board.
(6) The filter circuit according to (4) or (5), wherein the tip of the first projecting portion and the tip of the second projecting portion each have a circular shape, an elliptical shape, a rectangular shape, or a polygonal shape as viewed in the direction orthogonal to the main surface of the board.

It should be noted that the embodiments described above are intended to facilitate the understanding of the present disclosure and are not intended to limit the representation of the present disclosure. The present disclosure can be changed or improved without departing from the spirit thereof and the present disclosure includes equivalents thereof.

What is claimed is:

1. A filter circuit formed on a board, comprising:
an inductor comprising serially connected wiring line groups on a plurality of conductive layers of the board through one or more vias; and
a capacitor,
wherein, as viewed in a direction orthogonal to a main surface of the board, a first wiring line overlaps a third wiring line,
wherein the first wiring line includes a first end of the inductor,
wherein the third wiring line is on one of the plurality of conductive layers that is adjacent, in the direction orthogonal to the main surface of the board, to another of the plurality of conductive layers on which the first wiring line is formed, and
wherein the third wiring line has a first end electrically connected, through one of the vias, to a second wiring line, the second wiring line including a second end of the inductor.

2. The filter circuit according to claim 1, wherein the first wiring line and the third wiring line overlap each other so as to form a plus shape as viewed in the direction orthogonal to the main surface of the board.

3. The filter circuit according to claim 1, wherein the first wiring line and the third wiring line overlap each other so as to form a T-shape as viewed in the direction orthogonal to the main surface of the board.

4. A filter circuit formed on a board, comprising:
an inductor comprising serially connected wiring line groups on a plurality of conductive layers of the board through one or more vias; and
a capacitor,
wherein, as viewed in a direction orthogonal to a main surface of the board, a tip of a first projecting portion overlaps a tip of a second projecting portion,
wherein the first projecting portion is an inward projection of a first wiring line, the first wiring line including a first end of the inductor,
wherein the second projecting portion is an inward projection of a second wiring line, the second wiring line including a second end of the inductor,
wherein the first projecting portion is a portion of the first wiring line and has a winding shape, and
wherein the second projecting portion is a portion of the second wiring line.

5. The filter circuit according to claim 4, wherein a size of the tip of the first projecting portion is larger than a size of the tip of the second projecting portion as viewed in the direction orthogonal to the main surface of the board.

6. The filter circuit according to claim 4, wherein the tip of the first projecting portion and the tip of the second projecting portion each have a circular shape, an elliptical shape, a rectangular shape, or a polygonal shape as viewed in the direction orthogonal to the main surface of the board.

7. The filter circuit according to claim 5, wherein the tip of the first projecting portion and the tip of the second projecting portion each have a circular shape, an elliptical shape, a rectangular shape, or a polygonal shape as viewed in the direction orthogonal to the main surface of the board.
